(19) United States
(12) Patent Application Publication
(10) Pub. No.: US 2020/0243301 A1
(43) Pub. Date: Jul. 30, 2020

(54) PLASMA PROCESSING APPARATUS

(71) Applicant: EUGENE TECHNOLOGY CO., LTD., Yongin-si, Gyeonggi-do (KR)

(72) Inventors: Jeong Hee JO, Yongin-si, Gyeonggi-do (KR); Yoon Seok CHOI, Suwon-si, Gyeonggi-do (KR); Zaretskiy SERGEY, Yongin-si, Gyeonggi-do (KR); Cha Young YOO, Suwon-si, Gyeonggi-do (KR)

(73) Assignee: EUGENE TECHNOLOGY CO., LTD., Yongin-si, Gyeonggi-do (KR)

(21) Appl. No.: 16/755,098

(22) PCT Filed: Oct. 2, 2018
(86) PCT No.: PCT/KR2018/011691

§ 371 Date: Apr. 9, 2020

(30) Foreign Application Priority Data
Oct. 13, 2017 (KR) 10-2017-0133031

(51) Int. Cl. H01J 37/32

(52) U.S. Cl. CPC H01J 37/3211; H01J 37/32183; H01J 37/32146

(57) ABSTRACT

A plasma treatment apparatus according to the present invention includes an induction chamber in which a source gas is introduced to generate plasma therein, a process chamber in which a substrate to be treated is treated by the plasma generated in the induction chamber, an inductively coupled plasma (ICP) antenna disposed outside the induction chamber and configured to form an inductive magnetic field so as to generate plasma from the source gas introduced into the induction chamber, and a high-frequency oscillator configured to apply a RF power to the ICP antenna. The ICP antenna includes a plurality of helical antennas having the same length and center in a radial direction, each of the antennas includes an input terminal connected to the high-frequency oscillator and an output terminal disposed opposite to the input terminal and connected to the ground, and a balanced capacitor is mounted to the output terminal of each of the antennas so as to form a virtual ground at a center in a longitudinal direction of each of the antennas. The plurality of helical antennas are arranged so that input terminals and the output terminals thereof are spaced by the same angle with respect to the center in the radial direction, and the center in the longitudinal direction of each of the plurality of helical antennas is disposed between the output terminals of the plurality of helical antennas.

### TECHNICAL FIELD

The present invention relates to a plasma processing apparatus, and more particularly, to a ICP processing apparatus including an antenna to be able to improve a generation efficiency of plasma and a uniformity of plasma.

### BACKGROUND ART

In substrate processing devices used in a recent semiconductor process, a semiconductor circuit has been extremely miniaturized, a substrate for manufacturing the semiconductor circuit has been enlarged, and a liquid crystal display has had a wide area. Thus, there is trend that the entire processing areas have been enlarged but an internal circuit has been miniaturized. Accordingly, there is need for integrating much more elements in a limited area, and also researches and developments for improving the uniformity of the elements disposed on the entire enlarged surface are being conducted.

Plasma processing devices used as substrate processing devices are dry-type processing devices in which a reaction gas inside a chamber is made to be activated to form plasma and then a substrate is processed by the formed plasma, and the plasma processing devices are divided into a capacitively coupled plasma (CCP) method and an inductively coupled plasma (ICP) method, according to the type of an electrode.

The CCP method applies a high frequency to a pair of plate shape electrodes, which are generally parallel to each other, to generate plasma by means of an electric filed generated in a space between the electrodes, and thus the CCP method has the advantage that it has performances of the accurate capacity coupling adjustment and the ion adjustment to provide the high process productivity when compared to the ICP method. On the other hand, because energy of radio frequency power is generally exclusively transmitted to the plasma through the capacity coupling, the plasma ion density may be adjusted only by the increase or decrease in capacitively coupled radio frequency power. Therefore, the high radio frequency power is needed to generate the high density plasma. However, the increase in radio frequency power leads to increase ion impact energy. Therefore, in order to prevent damage due to the ion impact, there is a limitation to increase the radio frequency power to be supplied.

On the other hand, the ICP method applies a high frequency to an antenna that has generally a spiral (or helical) shape, and accelerates electrons of the inside of a chamber, by means of an electric filed induced according to a change of a magnetic field caused by high frequency current introduced to the antenna. Thus, it is known that the ICP method is appropriate to generate the high density plasma because it may easily increase the ion density as the radio frequency power increases but the ion impact resulting from the increase of the radio frequency power is relatively low. Also, comparing to the CCP method, the ICP method have a broad condition for plasma generation, that is, a pressure for gas and power. Therefore, in the substrate processing device using the plasma, it is a general trend that the ICP method is used to generate the high density plasma.

FIG. 1 is a schematic view showing a configuration for an inductively coupled plasma processing device of the prior art. Referring to FIG. 1, the inductively coupled plasma processing device 10 of the prior art includes: an inductive chamber 110 in which an inductively electric field is formed for generating plasma from a source; a processing chamber 120 in which a substrate W to be processed by plasma P is disposed; a gas introducing part 120 that supplies, to the inside of the inductive chamber 110, a source gas for processing the substrate; a gas discharging hole through which a residual gas and an unreacted gas after processing the substrate are discharged; a susceptor 140 which is disposed in the inductive chamber 110 and on which the substrate to be processed is disposed; an antenna 150 positioned in an upper portion or a sider surface of the inductive chamber 110 to provide a magnetic filed and an electric filed for generating plasma P in the chamber; a high frequency oscillator 160 (RF generator) for applying source power to the antenna; and an outer chamber to isolate the antenna from the outside.

Such an antenna for plasma source used in a plasma processing device may be classified into a cylindrical antenna, a flat type antenna, and a dome type antenna, according to a shape of an antenna and a dielectric window. However, since the antenna of ICP method causes non-uniform plasma in all directions due to a helical profile of an antenna coil, a stationary wave effect by a high frequency of a power applied to the antenna, and a distribution of an electric current in the antenna coil, it is difficult to secure the uniformity of the film.

### DISCLOSURE OF THE INVENTION

### Technical Problem

The present invention provides an ICP antenna and a substrate processing device including the same to be able to improve the plasma uniformity.

The present invention also provides an ICP antenna and a substrate processing device to be able to improve the efficiency of the ICP processing apparatus and the plasma uniformity by reducing the effects of capacitive coupled plasma(CCP), which may occur in the CCP processing apparatus.

Further another object of the present invention will become evident with reference to following detailed descriptions and drawings.

### Technical Solution

An embodiment of the present invention provides a plasma processing apparatus including: an induction chamber in which a source gas is introduced to generate plasma therein; a process chamber in which a substrate to be treated is treated by the plasma generated in the induction chamber; an inductively coupled plasma (ICP) antenna disposed outside the induction chamber and configured to form an inductive magnetic field so as to generate plasma from the source gas introduced into the induction chamber; and a high-frequency oscillator configured to apply a RF power to the ICP antenna, wherein the ICP antenna comprises a plurality of helical antennas having the same length and center in a radial direction, each of the antennas comprises an input terminal connected to the high-frequency oscillator and an output terminal disposed opposite to the input terminal and connected to the ground, and a balanced capacitor is mounted to the output terminal of each of the antennas so as to form a virtual ground at a center in a longitudinal direction of each of the antennas, and the plurality of helical antennas are arranged so that input terminals and the output terminals thereof are spaced by the same angle with respect to the center in the radial direction, and the center in the longitudinal direction of each of the plurality of helical antennas is disposed between the output terminals of the plurality of helical antennas.

The plurality of antennas comprise a first antenna and a second antenna, each of which comprises an input terminal and an output terminal, which are disposed symmetric with respect to the center in the radial direction, the input terminal and the output terminal of the first antenna are disposed symmetric to those of the second antenna with respect to the center in the radial direction, a center in a longitudinal direction of each of the first and second antennas is spaced by an angle of 90° from the output terminal of each of the first and second antennas with respect to the center in the radial direction, and the center in the longitudinal direction of the first antenna and the center in the longitudinal direction of the second antenna are disposed symmetric with respect to the center in the radial direction.

The plurality of antennas comprise first, second, and third antennas, each of which comprises an input terminal and an output terminal, which are disposed in the same direction with respect to the center in the radial direction, and the input terminal and the output terminal of each of the first, second, and third antennas are arranged at an angle of 120° with respect to the center in the radial direction, and a center in a longitudinal direction of each of the first, second, and third antennas is disposed symmetric to the input terminal of each of the first, second, and third antennas with respect to the center in the radial direction.

The plurality of antennas are parallel-connected to one high-frequency oscillator.

The plurality of antennas are connected to the high-frequency oscillator through an impedance matching circuit, and the plurality of antennas are connected to the high-frequency oscillator through one impedance matching circuit.

The plurality of antennas are connected to the high-frequency oscillator through an impedance matching circuit, and the plurality of antennas are connected to the high-frequency oscillator through impedance matching circuits, which are different from each other, respectively.

The plurality of antennas are independently connected to the high-frequency oscillator.

An embodiment of the present invention provides an ICP antenna that is disposed outside an induction chamber of an ICP treatment apparatus and forms an inductive magnetic field to generate plasma from a source gas introduced into the induction chamber, the ICP antenna comprising a plurality of helical antennas having the same length and center in a radial direction, wherein each of the antennas comprises an input terminal connected to the high-frequency oscillator and an output terminal disposed opposite to the input terminal and connected to the ground, and a balanced capacitor is mounted to the output terminal of each of the antennas so as to form a virtual ground at a center in a longitudinal direction of each of the antennas, and the plurality of helical antennas are arranged so that input terminals and the output terminals thereof are spaced by the same angle with respect to the center in the radial direction, and the center in the longitudinal direction of each of the plurality of helical antennas is disposed between the output terminals of the plurality of helical antennas.

The plurality of antennas comprise a first antenna and a second antenna, each of which comprises an input terminal and an output terminal, which are disposed symmetric with respect to the center in the radial direction, and the input terminal and the output terminal of the first antenna are disposed symmetric to those of the second antenna with respect to the center in the radial direction, a center in a longitudinal direction of each of the first and second antennas is spaced by an angle of 90° from the output terminal of each of the first and second antennas with respect to the center in the radial direction, and the center in the longitudinal direction of the first antenna and the center in the longitudinal direction of the second antenna are disposed symmetric with respect to the center in the radial direction.

The plurality of antennas comprise first, second, and third antennas, each of which comprises an input terminal and an output terminal, which are disposed in the same direction with respect to the center in the radial direction, and the input terminal and the output terminal of each of the first, second, and third antennas are arranged at an angle of 120° with respect to the center in the radial direction, and a center in a longitudinal direction of each of the first, second, and third antennas is disposed symmetric to the input terminal of each of the first, second, and third antennas with respect to the center in the radial direction.

### Advantageous Effects

The present invention may improve the plasma uniformity.

The present invention may improve the efficiency of the ICP treatment apparatus and the plasma uniformity by reducing the effects of capacitive coupled plasma (CCP), which may occur in the ICP treatment apparatus.

### DESCRIPTION OF DRAWINGS

FIG. 1 is a schematic view illustrating a constitution of an inductively coupled plasma treatment apparatus according to a related art.

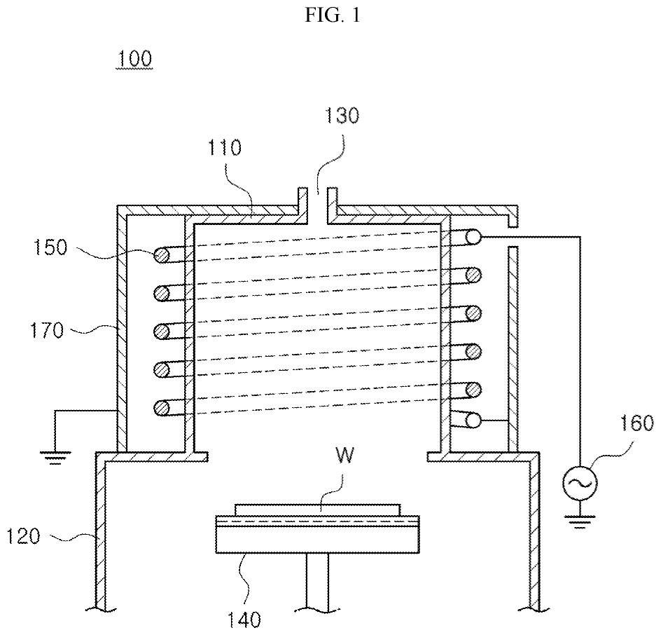

FIG. 2 is a view illustrating a cylindrical antenna according to the related art and magnitudes of a voltage and a current in a longitudinal direction of the cylindrical antenna.

FIG. 3 is a view illustrating a dual antenna according to the related art and magnitudes of a voltage and a current in a longitudinal direction of the dual antenna.

FIG. 4 is a view illustrating a dual antenna mounted with a balanced capacitor and magnitudes of a voltage and a current in a longitudinal direction of the antenna according to an embodiment of the present invention.

FIG. 5 is a view illustrating maximum current points of a dual antenna according to the related art and a dual antenna according to an embodiment of the present invention.

FIG. 6 is a view illustrating a triple antenna according to the related art and magnitudes of a voltage and a current in a longitudinal direction of the triple antenna.

FIG. 7 is a view illustrating a triple antenna mounted with a balanced capacitor and magnitudes of a voltage and a current in a longitudinal direction of the antenna according to another embodiment of the present invention.

FIG. 8 is a view illustrating maximum current points of a triple antenna according to the related art and a triple antenna according to another embodiment of the present invention.

FIG. 9 is a conceptual view illustrating an operation of an antenna mounted with a balanced capacitor.

### BEST MODE

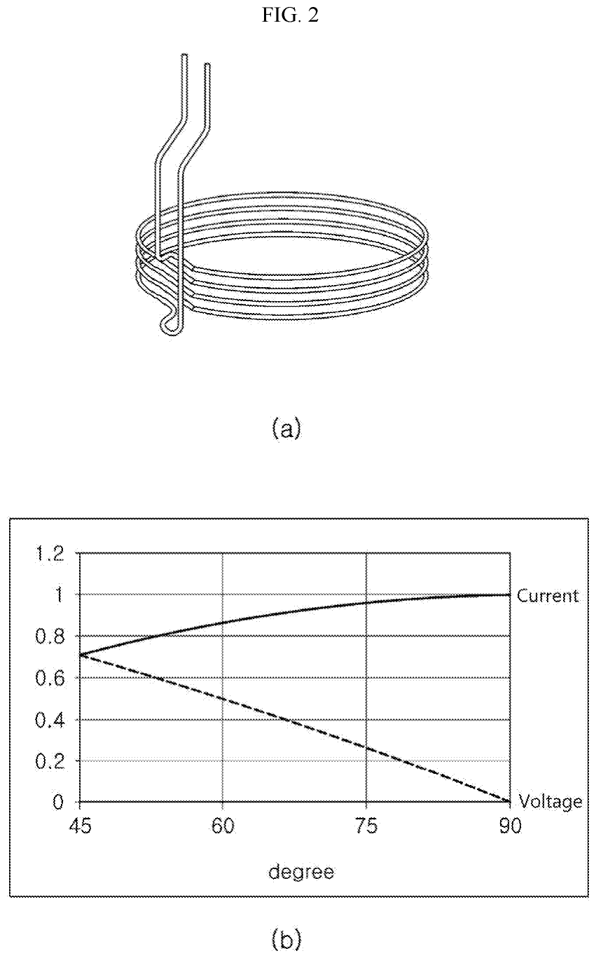

Hereinafter, preferred embodiments of the present invention will be described in more detail with reference to FIGS. 2 to 8. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration.

FIG. 2 is a view illustrating a cylindrical antenna according to a related art and magnitudes of a current and a voltage in a longitudinal direction of the cylindrical antenna. FIG. 2A is a schematic view illustrating an appearance of the cylindrical antenna according to the related art, and FIG. 2B is a view illustrating the magnitudes of a current and a voltage from an input terminal to an output terminal of the cylindrical antenna. In the specification, the input terminal refers to one end connected to a high frequency oscillator, and the output terminal refers to the other end through which the antenna is grounded. In general, in a coil antenna, a phase difference between a current and a voltage is about 90°. That is, in the coil antenna, a voltage has a maximum value at the input terminal and a minimum value (0V) at the output terminal that is a ground terminal, and a current has a minimum value at the input terminal and a maximum value at the output terminal that is the ground terminal. As illustrated in FIG. 2, when the cylindrical antenna has a coil length of λ/8(π/4), a minimum current may have a decreased value that is reduced by about 29.3% in comparison with a maximum current, and, as a result, plasma uniformity is not satisfactory due to ununiform current distribution caused by a current amplitude.

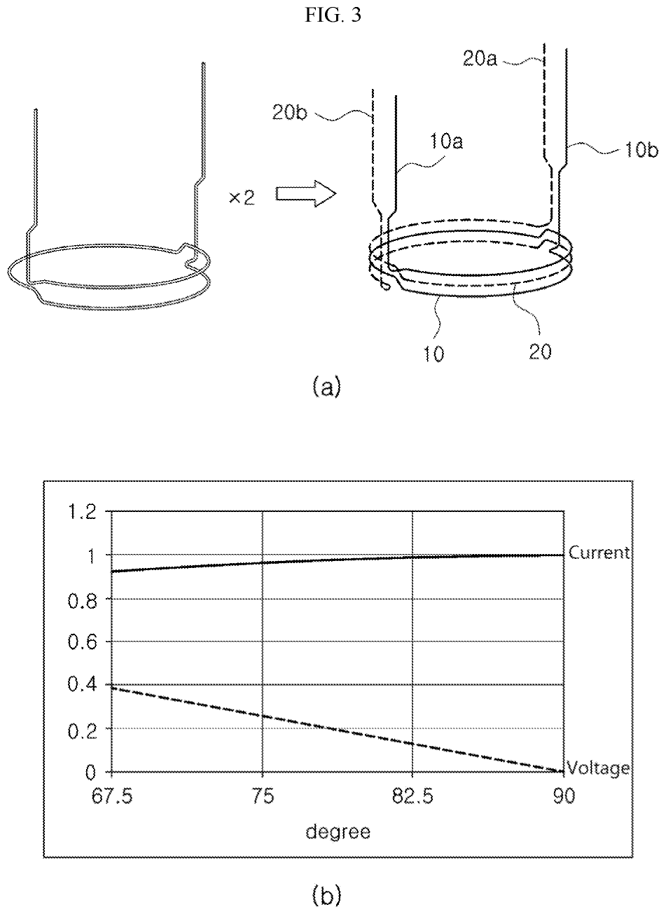

To resolve the above limitation, the applicant (Eugene technology Inc.) has developed a dual antenna that reduces the ununiform current distribution by using two antennas to allow the maximum current points to be symmetric to each other. FIG. 3 is a view illustrating the dual antenna according to the related art and the magnitudes of the current and the voltage in the longitudinal direction of the dual antenna. FIG. 3A is a schematic view illustrating the appearance of the dual antenna according to the related art, and FIG. 3B is a view illustrating the magnitudes of the current and the voltage from the input terminal to the output terminal of the dual antenna.

As illustrated in FIG. 3A, the dual antenna according to the related art includes two antennas, i.e., a first antenna 10 and a second antenna 20. The first antenna 10 and the second antenna 20 have approximately same constitution and function. In each antenna, the input terminal 10a and 20a and the output terminal 10b and 20b are symmetric to each other, and the input terminals 10a and 20a of the first antenna 10 and the second antenna 20 are symmetric to each other. In the embodiment, each of the antennas has a length of λ/16, which is reduced by ½ from the embodiment in FIG. 2, and the phase difference between the current and the voltage is about 90°. As illustrated in FIG. 3B, in case of the dual antenna according to the related art, a decreased value of the minimum current with respect to the maximum current is reduced by about 7.6% in comparison with the general antenna in FIG. 2, and thus the plasma uniformity due to the current distribution improves. Also, since the output terminals, which are maximum current points, face each other with respect to a central point of the antenna, as a result, the uniformity also improves.

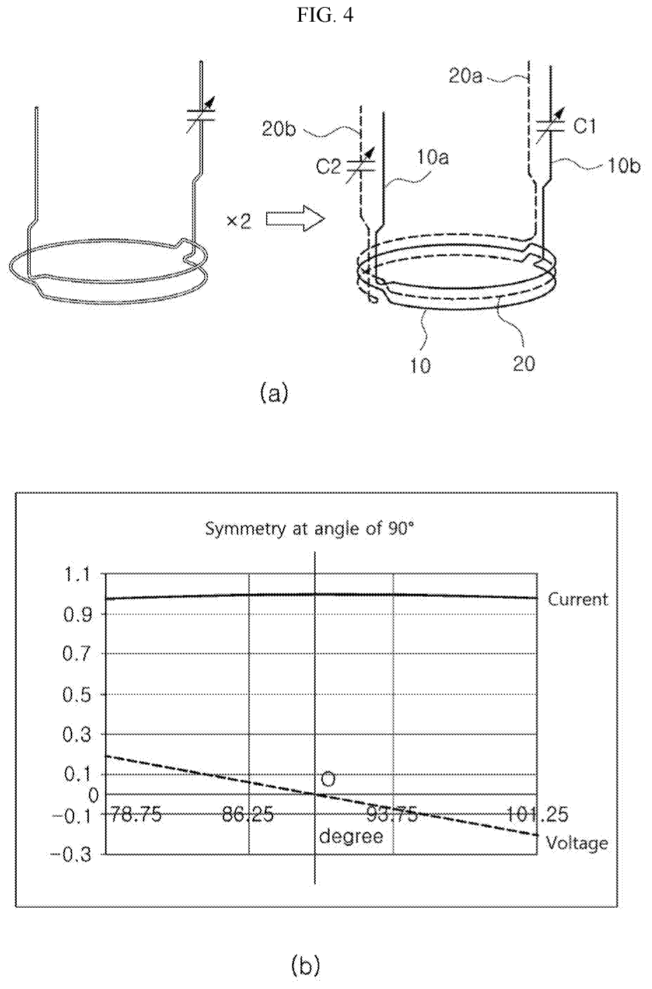

However, the uniformity improvement due to the symmetry of the dual antenna has a limitation. Thus, the inventor of the present application has developed the present invention capable of further improving the plasma uniformity by mounting a balanced capacitor to the output terminal to each of the antennas of the dual antenna, which is produced by own company. FIG. 4 is a view illustrating a dual antenna mounted with the balanced capacitor and the magnitudes of the current and the voltage in the longitudinal direction of the antenna according to an embodiment of the present invention.

As illustrated in FIG. 4, when viewed from the top (i.e., in terms of the plan view), the dual antenna according to an embodiment of the present invention may include the first antenna 10 and the second antenna 20, which are arranged such that the input terminal 10a and 20a and the output terminal 10b and 20b of each of the antennas are symmetric with respect to a center in a radial direction. Also, the input terminal 10a of the first antenna 10 is symmetric to the input terminal 20a of the second antenna 20 with respect to the center in the radial direction, and the output terminal 10b of the first antenna 10 is also symmetric to the output terminal 20b of the second antenna 20 with respect to the center in the radial direction. A center in a longitudinal direction of the first antenna 10 is disposed between the output terminal 10b of the first antenna and the output terminal 20b of the second antenna, and a center in a longitudinal direction of the second antenna 20 is also spaced by an angle of about 90° with respect to the center in the radial direction between the output terminal 10b of the first antenna and the output terminal 20b of the second antenna. That is, the center in the longitudinal direction of the first antenna 10 and the center in the longitudinal direction of the second antenna 20 may be symmetric to each other with respect to the center in the radial direction.

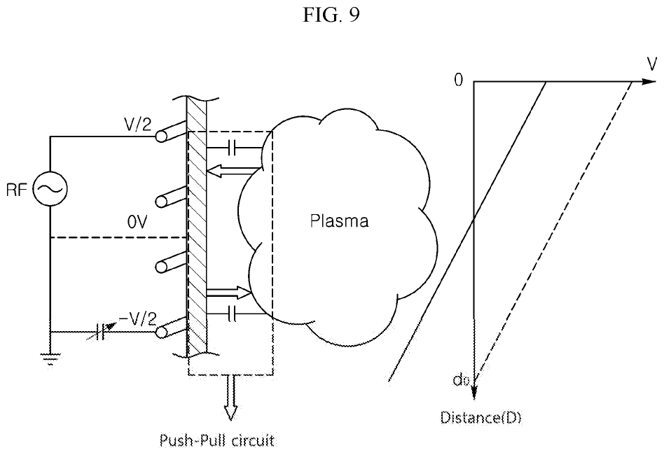

The dual antenna according to an embodiment of the present invention forms a virtual ground, which allows a voltage at the center of each of the antennas to be 0V, by mounting a capacitor C1 and C2 to the output terminal 10b and 20b of each of the antennas 10 and 20. For convenience of description, in the specification, the capacitor having a balanced condition for forming the virtual ground at the center of each of the antenna refers to the balanced capacitor. Effects of the balanced capacitor will be described in more detail with reference to FIG. 9. FIG. 9 is a conceptual view illustrating an operation of the antenna mounted with the balanced capacitor.

As known from FIG. 9, the virtual ground may be formed on the center of the antenna by mounting the balanced capacitor to the ground terminal of each of the antennas, and, in this case, the voltage is reduced by ½ with respect to the virtual ground in comparison with a case (expressed in dotted line) in which the virtual ground is not formed. Also, as a voltage having an opposite phase with respect to the virtual ground is formed, a push-pull circuit, in which a direction of a capacitive coupled capacitor (CCP) is opposite, is formed between plasma and the voltage. As described above, the voltage is reduced by mounting the balanced capacitor to the output terminal of the antenna, and the effects of the CCP may be reduced by forming the push-pull circuit. As a result, the inductively coupled plasma (ICP) efficiency may increase.

The above-described dual antenna according to an embodiment of the present invention may reduce the effects of the CCP due to decreased voltage by mounting the balanced capacitor to the output terminal of each of the antennas and offset the effects of the CCP by forming the push-pull circuit by the phase difference of about 180°, thereby improving the ICP efficiency. Thus, a plasma density may increase, and an electron temperature may decrease.

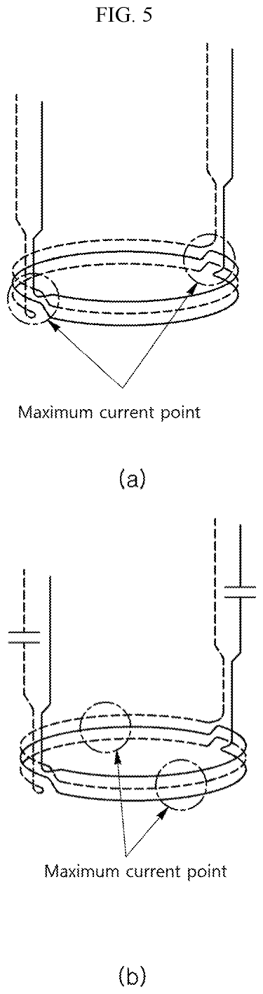

Also, as illustrated in FIG. 4B, the dual antenna according to an embodiment of the present invention decrease a deviation between a decreased value of the minimum current with respect to that of the maximum current by about 2% to improve the plasma uniformity due to the current distribution. Furthermore, as the maximum current point of each of the antennas moves to the center of the antenna from the output terminal of each of the antennas, when viewed from the top, the maximum current points of the first antenna 10 and the second antenna 20 are disposed between the input and output terminals and formed symmetric to each other with respect to the center of the antenna, thereby further improving the plasma uniformity. A relationship between the symmetry and position movement of the maximum current points and the plasma uniformity will be described in more detail with reference to FIG. 5.

FIG. 5 is a view illustrating the maximum current points of the dual antenna according to the related art and the dual antenna according to an embodiment of the present invention. As illustrated in FIG. 5A, the dual antenna according to the related art has the maximum current point at the output terminal of the antenna, and thus the maximum current point of the antenna is disposed on each of the input and output terminals, which are disposed symmetric with respect to the center in the radial direction. As illustrated in FIG. 5B, in the dual antenna mounted with the balanced capacitor according to an embodiment of the present invention, the maximum current point is disposed at a point forming about 90° with the input and output terminals with respect to the center in the radial direction.

As described above, in case of the dual antenna according to the related art, as the decreased value of the minimum current with respect to the maximum current decreases by about 7.6%, the plasma uniformity due to the current distribution improves.

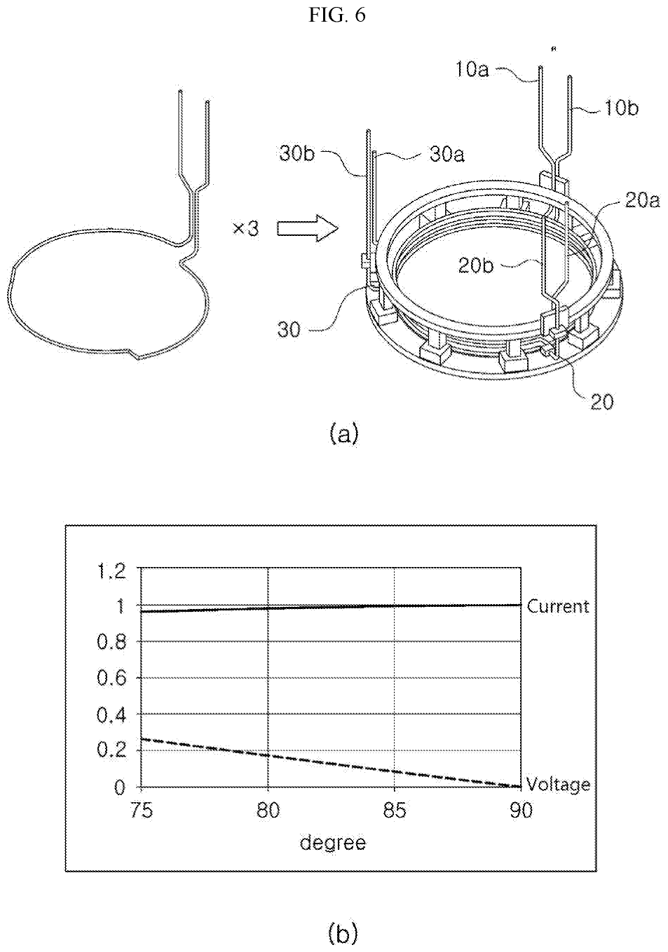

Hereinafter, an antenna according to another embodiment of the present invention will be described with reference to FIGS. 6 to 8. FIG. 6 is a view illustrating a triple antenna according to the related art and magnitudes of a voltage and a current in a longitudinal direction of the triple antenna. As illustrated in FIG. 6, the triple antenna according to the related art decreases an ununiform current distribution by symmetrically disposing maximum current points using three antennas. FIG. 6A is a schematic view illustrating the triple antenna according to the related art, and FIG. 6B is a view illustrating the magnitudes of a voltage and a current from an input terminal to an output terminal of each of antennas.

As illustrated in FIG. 6A, the triple antenna according to the related art includes three antennas, i.e., a first antenna 10, a second antenna 20, and a third antenna 30. The first antenna 10, the second antenna 20, and the third antenna 30 have the approximately same constitution and function. In each of the antennas, an input terminal 10a, 20a, and 30a and an output terminal 10b, 20b, and 30b are disposed in the same direction with respect to a center in a radial direction, and the input terminals of the antennas 10, 20, and 30 are arranged at an angle of 120° with respect to the center in the radial direction. In this embodiment, each of the antenna has a length of λ/24, which is reduced by ⅓ in comparison with the embodiment in FIG. 2, and a phase difference between a current and a voltage is about 90°. As illustrated in FIG. 6B, in case of the triple antenna according to the related art, a decreased value of a minimum current with respect to a maximum current decreases by about 3.4%, and thus the plasma uniformity due to the current distribution improves. Also, since the output terminals, which is a maximum current point, are equally spaced by about 120° with respect to a central point of the antenna, as a result, uniformity also improves.

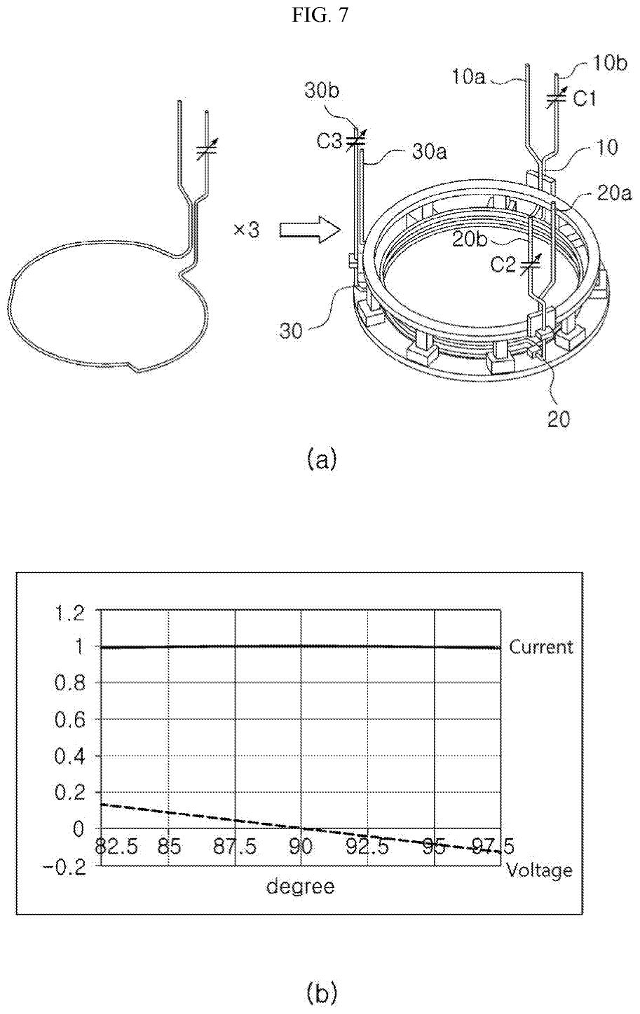

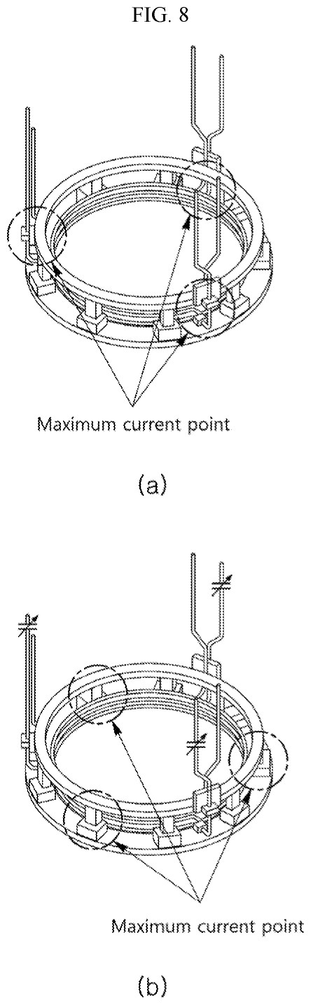

FIG. 7 is a view illustrating a triple antenna mounted with a balanced capacitor according to another embodiment of the present invention and magnitudes of a voltage and a current in a longitudinal direction of the antenna, and FIG. 8 is a view illustrating a triple antenna according to the related art and a maximum current point of a triple antenna according to another embodiment of the present invention.

The triple antenna according to an embodiment of the present invention in FIG. 7 includes a first antenna 10, a second antenna 20, and a third antenna 30, each of which includes an input terminal and an output terminal, which are disposed in the same direction with respect to the center in the radial direction like FIG. 6. The input and output terminals of each of the antennas 10, 20, and 30 may be arranged at an angle of about 120° with respect to the center in the radial direction, and centers in the longitudinal directions of antennas may be disposed symmetric with respect to the center in the radial direction and the input and output terminal of each of the antennas. That is, the center in the longitudinal direction of the first antenna 10 is disposed within 120° formed between the second antenna 20 and the third antenna 30 and forms an angle of 60° with the second antenna 20 and the third antenna 30 with respect to the center in the radial direction. Likewise, the center in the longitudinal direction of the second antenna 20 is disposed within 120° formed between the first antenna 10 and the third antenna 30 and forms an angle of 60° with the first antenna 10 and the third antenna 30 with respect to the center in the radial direction. Likewise, the center in the longitudinal direction of the third antenna 30 is disposed within 120° formed between the first antenna 10 and the second antenna 20 and forms an angle of 60° with the first antenna 10 and the second antenna 20 with respect to the center in the radial direction.

Balanced capacitors C1, C2, and C3 are mounted to output terminals 10b, 20b, and 30b of antennas 10, 20, and 30, respectively, in order to form a virtual ground at the center in the longitudinal direction of each of antennas under an applied high-frequency condition. As illustrated in FIG. 7B, the virtual ground is formed at the center in the longitudinal direction of the antenna by mounting the balanced capacitors C1, C2, and C3 to the output terminals 10b, 20b, and 30b of the antennas 10, 20, and 30, respectively. Accordingly, the maximum current point is disposed at the center in the longitudinal direction of the antenna. Thus, the decreased value of the minimum current with respect to the maximum current is only about 0.85%, so that the current distribution is uniformed, and the uniformity in plasma distribution improves.

Furthermore, as illustrated in FIG. 8A, in case of the triple antenna according to the related art, the maximum current point is disposed at the output terminal, and the ununiformity of the plasma distribution at the position is remarkable. However, as illustrated in FIG. 8B, in case of the triple antenna mounted with the balanced capacitor according to an embodiment of the present invention, the maximum current point is disposed at the center in the longitudinal direction of the antenna, and since the maximum current point is disposed symmetric with respect to the center in the radial direction between the output terminals of antennas when viewed from the top, the ununiformity of the plasma distribution at the output terminal may be resolved.

Although the embodiments of the dual antenna in which the input and output terminals are symmetrically disposed and the triple antenna mounted with the balanced capacitor are described as an example in the specification, the embodiments of the present invention are not limited thereto. For example, four or more antennas having the same length and the center in the radial direction may be provided, and even in this case, the uniformity of the plasma distribution may improve by mounting the balanced capacitor to the output terminal of each of the antenna in order to form the virtual ground at the center of the longitudinal direction of each of the antennas. In this case, a plurality of helical antennas are disposed so that the input terminal and the output terminal thereof are arranged at the same angle with respect to the center in the radial direction, and the centers in the longitudinal direction of the plurality of helical antennas are equally spaced between the output terminals of the plurality of helical antennas.

Also, although omitted for convenience of description in the present invention, a high-frequency oscillator is necessarily connected to the antenna to operate the antenna by using a plasma source. In this embodiment, the plurality of antennas may be parallel-connected to one high-frequency oscillator, and each of the antennas may be connected to the high-frequency oscillator through a matching circuit. In an embodiment, a plurality of antennas may be connected to the high-frequency oscillator through one impedance matching circuit.

In another embodiment, a plurality of antennas may be connected to the high-frequency oscillator through impedance matching circuits, which are different from each other, respectively. By using the mutually different impedance matching circuit, each of the antennas may perform impedance matching in more accurate manner according to characteristics of individual antennas. In another embodiment, each of a plurality of antennas may be independently connected to an individual high-frequency oscillator, and in this case, each of the antennas may be connected to the individual high-frequency oscillator through an individual matching circuit.

What is claimed is:

1. A plasma treatment apparatus comprising:
an induction chamber in which a source gas is introduced to generate plasma therein;
a process chamber in which a substrate to be treated is treated by the plasma generated in the induction chamber;
an inductively coupled plasma (ICP) antenna disposed outside the induction chamber and configured to form an inductive magnetic field so as to generate plasma from the source gas introduced into the induction chamber; and
a high-frequency oscillator configured to apply a RF power to the ICP antenna,
wherein the ICP antenna comprises a plurality of helical antennas having the same length and center in a radial direction, each of the antennas comprises an input terminal connected to the high-frequency oscillator and an output terminal disposed opposite to the input terminal and connected to the ground, and a balanced capacitor is mounted to the output terminal of each of the antennas so as to form a virtual ground at a center in a longitudinal direction of each of the antennas, and
the plurality of helical antennas are arranged so that input terminals and the output terminals thereof are spaced by the same angle with respect to the center in the radial direction, and the center in the longitudinal direction of each of the plurality of helical antennas is disposed between the output terminals of the plurality of helical antennas.

2. The plasma treatment apparatus of claim 1, wherein the plurality of antennas comprise a first antenna and a second antenna, each of which comprises an input terminal and an output terminal, which are disposed symmetric with respect to the center in the radial direction,
the input terminal and the output terminal of the first antenna are disposed symmetric to those of the second antenna with respect to the center in the radial direction, a center in a longitudinal direction of each of the first and second antennas is spaced by an angle of 90° from the output terminal of each of the first and second antennas with respect to the center in the radial direction, and the center in the longitudinal direction of the first antenna and the center in the longitudinal direction of the second antenna are disposed symmetric with respect to the center in the radial direction.

3. The plasma treatment apparatus of claim 1, wherein the plurality of antennas comprise first, second, and third antennas, each of which comprises an input terminal and an output terminal, which are disposed in the same direction with respect to the center in the radial direction, and
the input terminal and the output terminal of each of the first, second, and third antennas are arranged at an angle of 120° with respect to the center in the radial direction, and a center in a longitudinal direction of each of the first, second, and third antennas is disposed symmetric to the input terminal of each of the first, second, and third antennas with respect to the center in the radial direction.

4. The plasma treatment apparatus of claim 1, wherein the plurality of antennas are parallel-connected to one high-frequency oscillator.

5. The plasma treatment apparatus of claim 4, wherein the plurality of antennas are connected to the high-frequency oscillator through an impedance matching circuit, and
the plurality of antennas are connected to the high-frequency oscillator through one impedance matching circuit.

6. The plasma treatment apparatus of claim 4, wherein the plurality of antennas are connected to the high-frequency oscillator through an impedance matching circuit, and
the plurality of antennas are connected to the high-frequency oscillator through impedance matching circuits, which are different from each other, respectively.

7. The plasma treatment apparatus of claim 1, wherein the plurality of antennas are independently connected to the high-frequency oscillator.

8. An ICP antenna that is disposed outside an induction chamber of an ICP treatment apparatus and forms an inductive magnetic field to generate plasma from a source gas introduced into the induction chamber, the ICP antenna comprising
a plurality of helical antennas having the same length and center in a radial direction,
wherein each of the antennas comprises an input terminal connected to the high-frequency oscillator and an output terminal disposed opposite to the input terminal and connected to the ground, and a balanced capacitor is mounted to the output terminal of each of the antennas so as to form a virtual ground at a center in a longitudinal direction of each of the antennas, and
the plurality of helical antennas are arranged so that input terminals and the output terminals thereof are spaced by the same angle with respect to the center in the radial direction, and the center in the longitudinal direction of each of the plurality of helical antennas is disposed between the output terminals of the plurality of helical antennas.

9. The ICP antenna of claim 8, wherein the plurality of antennas comprise a first antenna and a second antenna, each of which comprises an input terminal and an output terminal, which are disposed symmetric with respect to the center in the radial direction, and
the input terminal and the output terminal of the first antenna are disposed symmetric to those of the second antenna with respect to the center in the radial direction, a center in a longitudinal direction of each of the first and second antennas is spaced by an angle of 90° from the output terminal of each of the first and second antennas with respect to the center in the radial direction, and the center in the longitudinal direction of the first antenna and the center in the longitudinal direction of the second antenna are disposed symmetric with respect to the center in the radial direction.

10. The ICP antenna of claim 8, wherein the plurality of antennas comprise first, second, and third antennas, each of which comprises an input terminal and an output terminal, which are disposed in the same direction with respect to the center in the radial direction, and
the input terminal and the output terminal of each of the first, second, and third antennas are arranged at an angle of 120° with respect to the center in the radial direction, and a center in a longitudinal direction of each of the first, second, and third antennas is disposed symmetric to the input terminal of each of the first, second, and third antennas with respect to the center in the radial direction.
